(19) United States
(12) Patent Application Publication
(10) Pub. No.: US 2009/0151769 A1
(43) Pub. Date: Jun. 18, 2009

(54) DEVICE AND SYSTEM FOR IMPROVED SOLAR CELL ENERGY COLLECTION AND SOLAR CELL PROTECTION

(76) Inventor: John C. CORBIN, Neshanic Station, NJ (US)

Correspondence Address: McGuire Woods LLP, Suite 1800, 1750 Tysons Boulevard, McLean, VA, 22102, US

(21) Appl. No.: 12/330,262

(22) Filed: Dec. 8, 2008

Related U.S. Application Data
(60) Provisional application No. 61/006,004, filed on Dec. 14, 2007.

(51) Int. Cl. H01L 31/052

(52) U.S. Cl. 136/246

(57) ABSTRACT

An apparatus, system and method are provided for optimizing energy retrieval from an array of solar cells and protecting the array of solar cells from weather-related conditions, including moving a reflector panel to a predetermined angular position on the basis of an ambient condition, or some other factor.

### CROSS REFERENCE TO PRIOR APPLICATIONS

This application claims priority and the benefit thereof from a U.S. Provisional Application No. 61/006,004 filed on Dec. 14, 2007, which is hereby incorporated by reference for all purposes as if fully set forth herein.

### BACKGROUND

1. Field

This invention relates to a device, a system and a method for improved solar energy collection and solar cell protection.

2. Related Art

Many low cost solar arrays, such as those employed in typical residential and small scale commercial use, employ low cost, relatively low efficiency photovoltaic (PV) or solar cells. Inverters used in these solar arrays convert direct current (DC) power received from the PV cells to alternating current (AC) power to be either used by homes or businesses, or to be fed back to a power grid. Inverters are relatively expensive, accounting for as much as 20% to 30% of the total cost of a PV system and are generally rated to slightly more than the expected maximum power output of the solar array. The efficiency of the inverters at converting DC to AC power falls off rapidly at low DC input levels. Therefore, under conditions like cloudy days, sunrise, or sunset, the energy generated from the low light levels is further decreased by the inefficiency of the inverters.

Historically, many solutions have tried to maximize solar energy striking PV cells. For example, mirrors and tracking systems have been used to maximize PV cell output. Mirrors, particularly focusing reflecting surfaces like parabolic mirrors, or Fresnel lenses are highly efficient at focusing available light onto a surface of a PV cell. Drawbacks to concentrating systems that employ highly specularly reflective surfaces or lens-based focusing systems may include, for example, heat build-up on the PV cells; dramatically lowered performance under hazy or cloudy conditions where sun light is scattered and less solar energy is available; and a need for high efficiency PV cells, such as, e.g., multi-junction cells.

Thus, as solar panels are more widely deployed in residential and commercial applications in varying climates, an unfulfilled need exists for a cost effective device or system that increases the efficiency of an array of PV cells and provides protection to the array during inclement weather.

### SUMMARY

In one aspect of the invention, an apparatus is provided that includes an array of solar cells for converting solar energy to electrical power. The apparatus comprises: a reflector panel configured to reflect solar energy to the array of solar cells; and an actuator configured to move the reflector panel to a predetermined angular position, wherein the actuator is further configured to move the reflector panel to a closed position to cover a portion of the array of solar cells. The apparatus may further comprise: an inverter coupled to the array of solar cells to receive DC power from the array of solar cells, wherein the inverter is configured to convert the received DC power to AC power. The reflector panel may comprise a non-rectangular configuration. The actuator may be further configured to move the reflector panel to the closed position based on a sensor feedback signal. The actuator may be further configured to move the reflector panel to the closed position based on a manual force exerted by a user. The apparatus may further comprise: a second reflector panel configured to cover a second portion of the array of solar cells; a third reflector panel configured to cover a third portion of the array of solar cells; and a fourth reflector panel configured to cover a fourth portion of the array of solar cells, wherein the second, third and fourth portions of the array of solar cells are different. The reflector panel and the second, third and fourth reflector panels may each be configured to be individually or simultaneously movable to the closed position. The sensor feedback signal may comprise at least one of a barometric pressure data, a rain data, an ice data, a snow data, a light data, or a GPS coordinate data. The reflector panel may comprise: a mirror; a reflective coating; a reflective film; a microprism; a reflective paint; or a cold light reflector. The reflective film may comprise: a metal; a metal film; or a glass bead film. The actuator may comprise a low-energy consumption device that includes a switch, a relay or a DC motor. The properties of the reflector panel may provide for reflectance that includes incident radiation reflected light reflected as a combination of specular and diffuse reflection.

According to another aspect of the invention, a method is provided for optimizing energy retrieval from an array of solar cells and protecting the array of solar cells from weather-related conditions. The method comprises: moving a reflector panel to a predetermined angular position on the basis of an ambient condition. The predetermined angular position may comprise a closed position to cover the array of solar cells. The method may further comprise: receiving sensor feedback data from a sensor assembly; and moving the reflector panel to the predetermined angular position based on the sensor feedback data. The sensor feedback data may comprise at least one of a barometric pressure data, a rain data, an ice data, a snow data, a light data, or a GPS coordinate data. The moving may comprise driving a low-energy consumption DC motor. The method may further comprise: moving a second reflector panel configured to cover a second portion of the array of solar cells; moving a third reflector panel configured to cover a third portion of the array of solar cells; and moving a fourth reflector panel configured to cover a fourth portion of the array of solar cells, wherein said reflector panel and said second, third and fourth reflector panels are simultaneously moved to completely cover the array of solar cells to protect the cells from weather-related conditions.

In yet another aspect of the invention, a computer readable medium comprising a program that, when executed, causes optimizing energy retrieval from an array of solar cells and protecting the array of solar cells from harmful ambient conditions. The medium may comprise a reflector panel moving code section that, when executed, causes a reflector panel to move to a predetermined angular position on the basis of an ambient condition. The predetermined angular position may comprise a closed position to cover the array of solar cells. The medium may further comprise: a sensor feedback section that, when executed, causes receiving a sensor feedback data from a sensor assembly, wherein the reflector panel is moved to the predetermined angular position based on the sensor feedback data. The sensor feedback data may comprise at least one of a barometric pressure data, a rain data, an ice data, a snow data, a light data, or a GPS coordinate data.

Additional features, advantages, and embodiments of the invention may be set forth or apparent from consideration of the following detailed description, drawings, and claims. Moreover, it is to be understood that both the foregoing summary of the invention and the following detailed description are examples and are intended to provide further explanation without limiting the scope of the invention as claimed.

### BRIEF DESCRIPTION OF THE DRAWINGS

The accompanying drawings, which are included to provide a further understanding of the invention, are incorporated in and constitute a part of this specification, illustrate embodiments of the invention and together with the detailed description serve to explain the principles of the invention. No attempt is made to show structural details of the invention in more detail than may be necessary for a fundamental understanding of the invention and the various ways in which it may be practiced. In the drawings:

FIGS. 1A, 1B show an example of a front elevation view of a PV system according to an embodiment of the invention in an open and a closed configuration, respectively;

FIG. 2 shows an example of a PV control system for controlling a PV system;

FIG. 3 shows an example of a process that may be used to drive a PV system;

FIGS. 4A, 4B, 4C and 4D show various views of an alternative embodiment of a PV system according to the invention; and

FIGS. 5A, 5B and 5C show various views of a further alternative embodiment of a PV system according to the invention.

### DETAILED DESCRIPTION

The embodiments of the invention and the various features and details thereof are explained more fully with reference to the non-limiting embodiments and examples that are described and/or illustrated in the accompanying drawings and detailed in the following description. It should be noted that the features illustrated in the drawings are not necessarily drawn to scale, and features of one embodiment may be employed with other embodiments, even if not explicitly stated herein. Descriptions of well-known components and processing techniques may be omitted so as to not unnecessarily obscure teaching principles of the disclosed embodiments. The examples used herein are intended merely to facilitate an understanding of ways in which the invention may be practiced and to further enable those of skill in the art to practice the disclosed embodiments. Accordingly, the examples and embodiments disclosed herein should not be construed as limiting. Moreover, it is noted that like reference numerals represent similar parts throughout the several views of the drawings.

The present invention provides a device, a system and a method for increasing the amount of available sunlight striking an array of photovoltaic (PV) cells while in use, and providing protection to the array of PV cells in inclement conditions. This device, system and method employ reflector (or reflective) panels that may be attached to a PV module comprising the array of PV cells. The PV module may include one or more arrays of PV cells, each array being configured in a plurality of rows and columns of PV cells, and at least one inverter for converting received DC energy from the PV cells to usable AC energy, which may be output to a home, business, power grid, and the like. Each of the reflector panels includes a reflective surface that, when deployed, increases the solar radiation striking the light sensing portion (surface) of the PV module. The reflective surface may be on one or both sides of the reflector panel. The PV module may include a glass cover, a thin-film cover, a plastic cover, or the like, to cover the PV cells. These reflector panels vary from highly diffusely reflective to largely specularly reflective, but the performance of the system rather than relying on the ability to highly focus the solar radiation on any particular spot or area of the PV module instead may operate best with Lambertian reflectance, or as described a Phong reflectance, like that used in computer graphics. The invention may operate best when it increases the overall reflectance but does not require focusing of the reflected light on specific locations on the PV module, thereby avoiding overheating and degrading the PV cells in the PV module and/or overloading the inverters employed with the PV module. In addition, since cloudy or hazy days may mean that incident radiation is already being scattered, this invention improves the efficiency of PV modules (or solar panels) even under such conditions as it can collect and reflect even highly scattered incident radiation.

Furthermore, the reflector panels of the invention provide protection for the PV module under inclement weather conditions. The reflector panels may be configured to fold or slide back over the surface of the PV module, thereby providing a protective cover for the PV module to protect the PV module, including the PV cells, from inclement weather conditions by preventing snow or ice build up on the surface of the PV module, protecting against hail and wind driven objects, and reducing the surface area of the array and thus the wind loading. Operation of the reflector panels and the protection they afford can be controlled by a system with relatively manual operations, e.g. switches or levers, to deploy or close the reflector panels. Alternatively, the system can be linked to a sensor network that monitors light, power, weather and similar conditions to improve energy collection and stow the reflector panels to protect the PV module and PV cells when inclement conditions are detected.

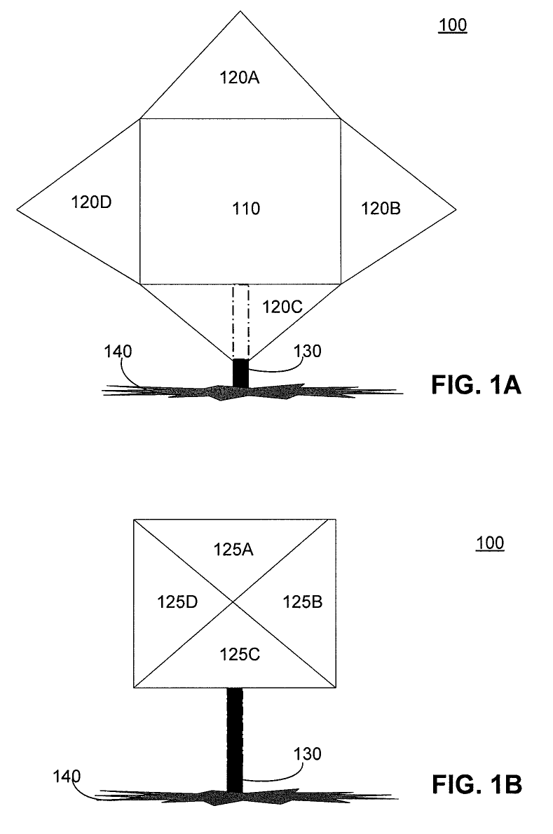

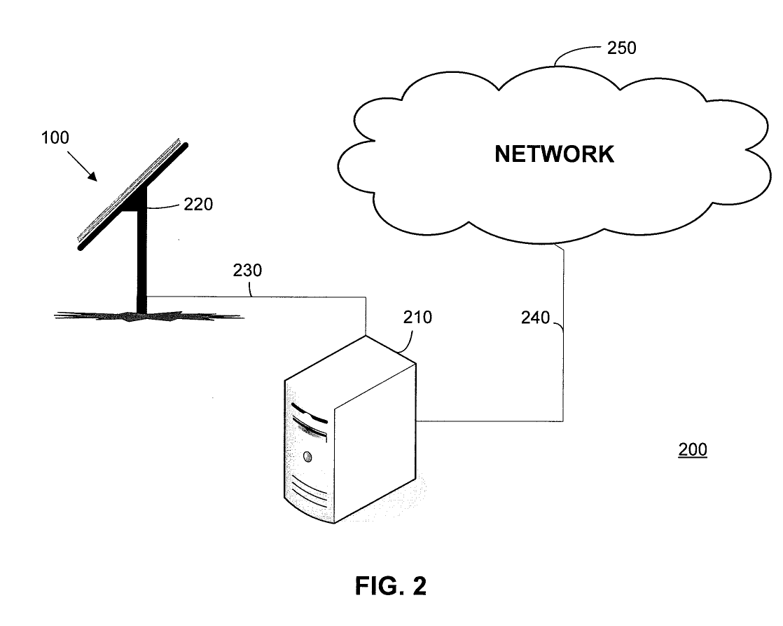

FIG. 1A shows an example of a front elevation view of a PV system 100 in an open (or deployed) configuration, according to an embodiment of the invention. The PV system 100 includes a PV module 110, a plurality of reflector (or reflective) panels 120A, 120B, 120C, 120D, and a support mechanism 130 (such as, e.g., a pole, a post, a bracket, a linear actuator, or the like) coupled to a surface 140. The support mechanism 130 may include an actuator system (not shown), as discussed below with regard to FIG. 2. The surface 140 may include for example, without limitation, a ground surface, a fluid surface (such as, e.g., a lake, a pond, or the like) a structural surface (such as, e.g., a roof, a side wall, a window ledge, or the like).

The PV module 110 may include one or more modules of PV (or solar) cells (not shown) that are configured in a planar-array structure (such as, e.g., a plurality of cells configured in rows and columns of a two-dimensional plane). The PV module 110 may include, for example, without limitation, one or more arrays of flat panel PV cells or thin-film flexible cells. The PV cells may include single junction or multijunction PV cells configured in single or multiple layers. The PV cells may further include, for example, without limitation, any one or more of the following: a crystalline silicon cell (such as, e.g., monocrystalline cell, polycrystalline cell, amorphous cell, and the like); a cadmium telluride cell; a copper indium gallium selenide cell; a indium gallium phosphide cell; indium gallium arsenide; a germanium cell; a amorphous silicon cell; a micromorphous silicon cell; a gallium arsenide cell; and the like. The PV cells may include wafer-based cells, thin-film based cells, or the like, supported by, for example, without limitation, a glass, a ceramic, a metal, a plastic, a fiberglass, or the like. Further, the PV cells may be covered by a glass, a plastic, or the like. Additionally, the PV module 110 may include one or more inverters (not shown), one or more batteries (not shown), one or more interconnecting electrical lines (not shown) (such as, e.g., electrical conductors, wires, and the like). Furthermore, the PV module 110 may employ excess thermal generation of the PV cells to enhance voltages or carrier collection as is known in the art.

Although shown as a rectangular structure, the PV module 110 may be configured in any size or shape, including, without limitation, a planar structure (such as, e.g., a square, a circle, a triangle, a pentagon, and the like), a three-dimensional structure (such as, e.g., a cylinder, a sphere, a pyramid, and the like), or any combination thereof.

The reflector panels 120A, 120B, 120C, 120D are configurable to be positioned to provide most effective conversion of available solar light into energy within the power conversion constraints of the PV system 100 and the PV module 110. Each of the reflector panels 120A to 120D may include, for example, one or more of any of the following, without limitation: a mirror, a coating, a film, a microprism, a paint, or any other material suitable to highly-efficiently reflect visible to near-ultraviolet wavelengths. Examples of suitable materials include, without limitation, metal and metal films, glass bead films like those used in road reflective films, pigmented painted surfaces like those with titanium, or any other surfaces capable of efficiently reflecting visible to near-ultraviolet wavelengths. A preferred material should include high reflection characteristics for visible to near-ultraviolet wavelengths of light and high transmission of infrared wavelengths of light—often termed “cold light reflectors.” Some polymeric films and metal coatings have these properties.

The reflector panels 120A, 120B, 120C, 120D should increase the amount of light impinging on the PV module 110 to, for example, yield improved energy conversion from the PV cells (not shown). The panels 120A to 120D may be able to increase the amount of impinging light without, for example, generating excess heat from highly focusing the radiation on the PV module 110 or requiring sophisticated tracking to accurately focus reflected light on to the PV module 110.

While it is preferred that the reflector panels 120A, 120B, 120C, 120D are configured to have substantially the same size, shape, composition, reflectivity, transmissibility, heat absorption/dissipation, and the like, and covering equal portions of the PV module 110 when positioned in the closed configuration, it is noted that this is not a requirement. Instead, each of the reflector panels 120A to 120D may be substantially different from each of the other panels in terms of size, shape, composition, reflectivity, transmissibility, heat absorption/dissipation, and the like. For example, the reflector panels 120A, 120B, 120C and 120D may be configured to include, without limitation, a planar structure (such as, e.g., a square, a circle, a rectangle, a pentagon, and the like), a three-dimensional structure (such as, e.g., a cylinder, a sphere, a pyramid, and the like), or any combination thereof, without departing from the scope or spirit of the invention.

Regardless of the size or shape of the reflector panels 120A, 120B, 120C and 120D, the reflector panels 120A-120D should be configurable to provide the most effective conversion of available sun light into energy within the power conversion constraints of the PV system 100. Furthermore, the reflector panels 120A to 120D should be configurable to provide complete coverage of the PV module 110 to completely protect the PV cells from external conditions, such as, e.g., but not limited to harsh weather (including snow, ice, hail, wind, lightening, flying objects, or the like).

Furthermore, regardless of the size or shape of the reflector panels 120A, 120B, 120C and 120D, the panels 120A to 120D should be configured to be movable and to fully and completely cover the surface of the PV module 110 when positioned in the stowed-away configuration. FIG. 1B shows a front elevation view of the PV system 100 when the panels 120A, 120B, 120C, 120D are configured in a closed or stowed-away configuration. In the stowed-away configuration, the reflector panels 120A, 120B, 120C, 120D are safely stowed, minimizing wind resistance of the PV system 100 and protecting the PV module 110 in adverse weather conditions.

Referring to FIG. 1B, each of the reflector panels 120A, 120B, 120C, 120D includes a respective back panel 125A, 125B, 125C, 125D, and a movable coupling mechanism (not shown) that movably couples each of the reflector panels 120A, 120B, 120C, 120D to the PV system 100. The back panels 125A, 125B, 125C, 125D may include, for example, without limitation, a glass material, a ceramic material, a metal material, a plastic material, a fiberglass material, a wood material, or any other suitable material that is capable of withstanding adverse ambient (external) conditions (such as, e.g., rain, lightening, hail, snow, ice, wind, cold, heat, fire, flying objects, or the like) and may be the same material as the reflective surface. Furthermore, the back panels 125A, 125B, 125C, 125D may be configured to securely lock in a stowed-away configuration (e.g., shown in FIG. 1B) to prevent tampering, vandalism, theft, or the like of the light sensing/reflecting parts of the PV system 100.

The geometry of the reflector panels 120A to 120D shown in FIGS. 1A and 1B might be preferable in conditions where ice or snow could cover the surfaces of the PV module and/or reflector panels, as opening multiple panels would minimize the weight and strain associated with opening any single reflector panel. A wide range of other configurations for the reflector panels is possible and the examples should not be construed as a limitation of the invention. The movement of the panels may be done independently or in concert (simultaneously).

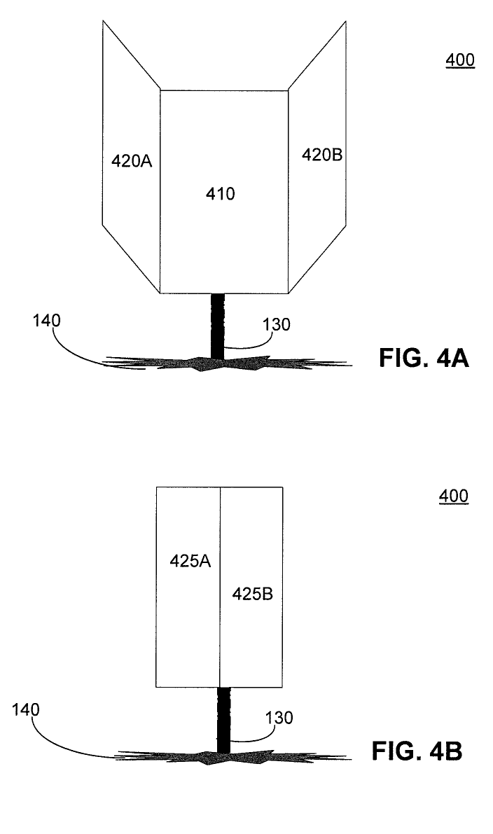

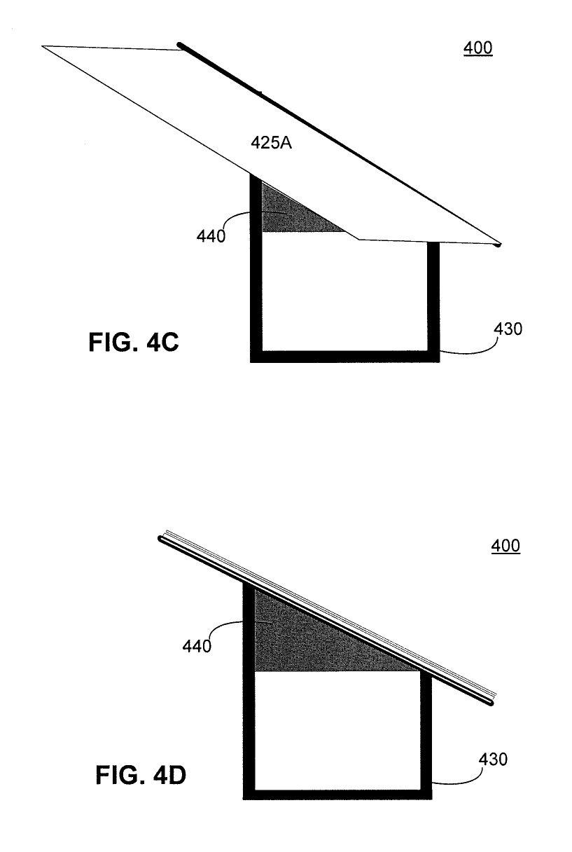

FIG. 2 shows an example of a PV control system 200 that may be used to automatically control the PV system 100. The PV control system 200 includes the PV system 100, a computer 210, an actuator system 220, communication links 230, 240 and a network 250. The PV system 100 may be the same as the PV system 100 in FIGS. 1A, 1B, or the PV System 400 in FIGS. 4A, 4B, 4C, 4D, discussed below, or any other PV system configured in accordance with the scope and spirit of the present invention.

The PV system 100 may include an actuator system 220 (shown in FIG. 2) for moving (or actuating) the reflector panels 120A, 120B, 120C, 120D, individually or simultaneously, from the open configuration (shown in FIG. 1A) to the closed or stowed-away configuration (shown in FIG. 1B). In this regard, a movable coupling mechanism (not shown) may be provided for each of the reflector panels 120A, 120B, 120C, 120D. The movable coupling mechanism may include, for example, without limitation, a hinge along an adjoining edge of the reflector panel, a ball-and-socket joint, a rack-and-pinion assembly, sliding assembly or the like, or any combination thereof. Moreover, the movable mechanism may be configured to pivotally move a respective panel 120A, 120B, 120C, 120D to a particular angular position (such as, e.g., an angle that provides optimum light flux to the sensing surface of the PV module 110 without overloading or overheating the PV module 110), which is located between the closed or stowed-away configuration (e.g., shown in FIG. 1B), i.e., where the reflective surface of the respective panel 120A, 120B, 120C, 120D is in the same plane as the PV module 110 and facing the PV module 110 (forming an angle of about zero (0°) degrees with the PV module 110) and the open configuration (e.g., shown in FIG. 1A), i.e., where the plane of the reflective surface of the respective panel 120A, 120B, 120C, 120D forms an angle of less than ninety degrees (90°) with the normal to the sensing surface of the PV module 110. The actuator system 220 may be configured to pivotally move or drive each of the reflector panels 120A, 120B, 120C, 120D individually or simultaneously to the particular position. The particular angular position of the reflector panels 120A, 120B, 120C, 120D may vary based on, for example, a position of the sun relative to the normal of the sensing surface of the PV module 110, or based on a position arbitrarily selected by a user.

Preferably, the actuator system 220 may include low-energy consumption devices, such as, for example, without limitation, one or more low-voltage DC motors (not shown), one or more switches (not shown), one or more relays (not shown) a gear assembly (not shown), a gear and lever assembly (not shown), a linear actuator (not shown) (e.g., a DC motor driven lead screw type), a cable and winch system (not shown), a hydraulic drive assembly (not shown), a shape memory actuator (not shown), a hinge-and-pulley assembly (not shown), or the like. The actuator system 220 may be controlled manually or automatically to both open and close the reflector panels 120A, 120B, 120C, 120D, as well as to precisely position the reflector panels 120A, 120B, 120C, 120D, to the particular angular position that provides optimum PV cell performance (such as, e.g., when an optimum light flux is provided to the energy sensing surface of the PV module 110 without overloading or overheating the module). The reflector panels 120A, 120B, 120C, 120D, may be moved individually, or two or more of the panels may be moved simultaneously.

For manual operation, the PV system 100 may include an interface device (not shown) for controlling the low-voltage consumption devices. The Interface device may include, for example, without limitation, one or more switches and one or more relays to allow a human operator to control power supply to, e.g., the low-voltage DC motor to drive the reflector panels 120A, 120B, 120C, 120D. The interface device may include a remote computer (not shown) that is in communication with the computer 210 through the communication link 240 and network 250, exchanging data signals and control signals between the remote computer and the computer 210. The remote computer may be similar to the computer 210.

Alternatively, for manual operation, the PV system 100 may include, for example, without limitation, a gear-assembly (not shown), a rack-and-pinion (not shown), a lead-screw linear actuator (not shown), or a cable and winch system (not shown) that may be operable by a force exerted by a user.

The actuator system 220 may be configured for multi-axis tracking combined with positioning of the one or more reflector panels 120A to 120D. The actuator system 220 may be configured for manual, semi-automated or fully automated operation. In this regard, the actuator system 220 (or the PV system 100) may include an internal computer, such as, e.g., computer 210 (discussed below), or it may be externally controlled by the computer 210 through the communication link 230. The computer 210 may control the actuator system 220 for semi-automated or fully automated operation based on, for example, without limitation, a wind vector (including wind direction, wind speed, changes in direction and/or speed with respect to time, and the like), atmospheric pressure, precipitation (e.g., rain, snow, ice, hail), ambient temperature, PV cell temperature, power usage (instantaneous and/or historical usage), power demand, light intensity (including continuous and real-time sensing to track the sun), GPS coordinates, the season of the year, a time, a date, or the like.

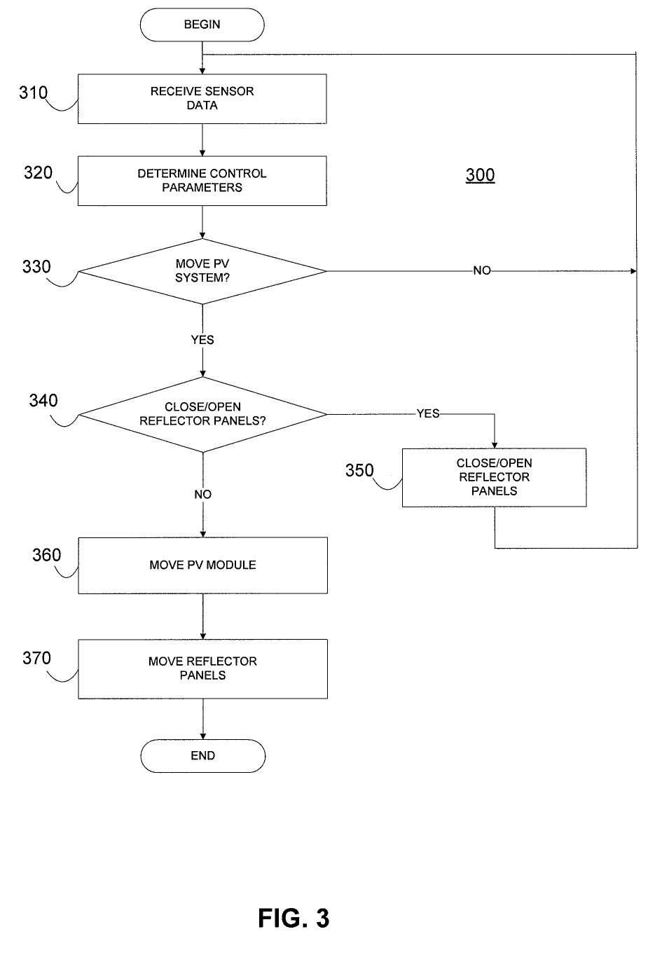

Furthermore, the PV system 100 may include a sensor assembly (not shown), which may be configured to sense conditions and provide sensor data such as, for example, but not limited to, anemometer data, barometric pressure data, precipitation sensor data (such as, e.g., rain, ice, snow, hail, etc.), temperature data (such as, e.g., ambient temperature, temperature of the PV cells, temperature proximate the PV cells, and the like), power data (such as, e.g., current usage, historical usage, predicted usage, and the like), light sensor data, GPS coordinate data, end of travel of the PV module 110 tracking system, and the like. The computer 210 (which may be located in the PV system 100, or external to the PV system 100 as shown in FIG. 2) may generate control signals based on the sensed data, as discussed below with regard to FIG. 3.

The computer 210 may include any machine, device, circuit, component, or module, or any system of machines, devices, circuits, components, modules, or the like, which are capable of manipulating data according to one or more instructions, such as, for example, without limitation, a processor, a microprocessor, a central processing unit, a general purpose computer, a personal computer, a laptop computer, a palmtop computer, a notebook computer, a desktop computer, a workstation computer, a server, or the like, or an array of processors, microprocessors, central processing units, general purpose computers, personal computers, laptop computers, palmtop computers, notebook computers, desktop computers, workstation computers, servers, or the like.

The communication links 230, 240 may each be a wired link, a wireless link, an optical link, or any combination thereof. The communication links 230, 240 may include additional hardware to facilitate communication between the computer 210 and the PV system 100, and/or between the computer 210 and the network 250. Furthermore, the communication links 230, 240 may be integrated into a network, such as, for example, a local area network (LAN), a wide area network (WAN), a personal area network (PAN), a broadband area network (BAN), and the like, any of which may be configured to communicate data via a wireless and/or a wired communication medium.

The network 250 may include, but is not limited to, for example, any one or more of a personal area network (PAN), a local area network (LAN), a campus area network (CAN), a metropolitan area network (MAN), a wide area network (WAN), a broadband network (BBN), the Internet, or the like. Further, the network 250 may include, but is not limited to, for example, any one or more of the following network topologies, including a bus network, a star network, a ring network, a mesh network, a star-bus network, tree or hierarchical network, or the like.

FIG. 3 shows an example of a process that may be used to drive the PV system 100 (shown in FIG. 2).

Referring to FIGS. 2 and 3, the computer 210 receives sensor data from the sensor assembly (not shown) provided in, or near the PV system 100 (Step 310). Based on the received sensor data, an internal status data (such as, e.g., time, date, and the like) and a user-defined data (discussed below), the computer 210 may determine control parameters, such as, for example, whether to close/open one or more of the reflector panels 120A to 120D, a particular angular position for each (or all) reflector panel(s) and a particular azimuth-altitude angle pair (φ, θ) (Step 320). The user-defined data may be received by the computer 210 from a user over the network 250 through the communication link 240. The user-defined data may include, for example, without limitation, one or more override instructions, such as to close/open one or more of the reflector panels 120A to 120D of the particular PV system 100, a particular angular position to which each (or all) of the reflector panels 120A to 120D are to be moved, a particular azimuth-altitude angle pair (φ, θ) to which the PV system 100 is to be moved, and the like. Additionally, the user-defined data may include, for example a particular time, date, ambient condition, or any combination thereof, at which the override instruction(s) is to be carried out.

After the control parameters have been determined (Step 320), a determination is made whether to move the PV system 100 based on the control parameters (Step 330). If a determination is made to move the PV system 100 (“YES,” Step 330), then a determination is made whether to close/open one or more (or all) of the reflector panels 120A to 120D (Step 340), otherwise the process returns to receive further sensor data (“NO,” Step 330, then Step 310). If a determination is made to close/open the one or more (or all) reflector panels 120A to 120D (“YES,” Step 340), then the actuator system 220 may be driven to close/open the one or more (or all) reflector panels 120A to 120D (Step 350).

However, if a determination is made not to close/open the one or more (or all) reflector panels 120A to 120D (“NO,” Step 340), then the PV system 100 may be moved to the determined azimuth-altitude angle pair (φ, θ) (Step 360). Further, the reflector panels 120A to 120D may each be moved individually (or simultaneously) to the determined angular position for each respective reflector panel 120A to 120D, which may be the same or different for each reflector panel (Step 370).

Alternatively, the determination of whether to move the PV system (Step 330) may be carried out after the determination of whether to close/open the reflector panels 120A to 120D (Step 340). Further, the PV module may be moved (Step 360) after the one or more reflector panels are moved (Step 370).

The process 300 may be continuously repeated as a nested loop, or it may be carried out at predetermined times, such as, for example, for semiannual adjustment, or under one-time control by a user.

According to a further aspect of the invention, a computer program is provided on a tangible computer readable recording medium having instructions, which when executed on a general purpose computer, may cause each of the Steps 310 through 370 to be carried out. The medium may include code section or code segment for each of the Steps 310 through 370 shown in FIG. 3 and described herein, such that when executed on a general purpose computer, the code sections cause the computer to carry out the process 300 shown in FIG. 3.

FIGS. 4A, 4B, 4C and 4D show various views of an alternative embodiment of a PV system 400 according to the invention. FIG. 4A shows a front elevation view of the PV system 400 in an open configuration. FIG. 4B shows a front elevation view of the PV system 400 in a closed configuration. FIG. 4C shows a side view of the PV system 400 in the open configuration. FIG. 4D shows a side view of the PV system 400 in the closed configuration.

As seen in FIGS. 4A to 4D, the PV system 400 includes a PV module 410, a pair of rectangular reflector panels 420A, 420B, a support mechanism 430 (such as, e.g., a rigid base, a bracket, or the like) and an actuator system 440. The reflector panels 420A, 420B include back panels 425A, 425B. The PV module 410 may be similar to the PV module 110 shown in FIG. 1. The actuator system 440 may be similar to the actuator system 220 shown in FIG. 2. The reflector panels 420A, 420B may be similar in performance and composition to the reflector panels 120A to 120D shown in FIG. 1A. Further, the back panels 425A, 425B may be similar to the back panels 125A to 125D shown in FIG. 1B.

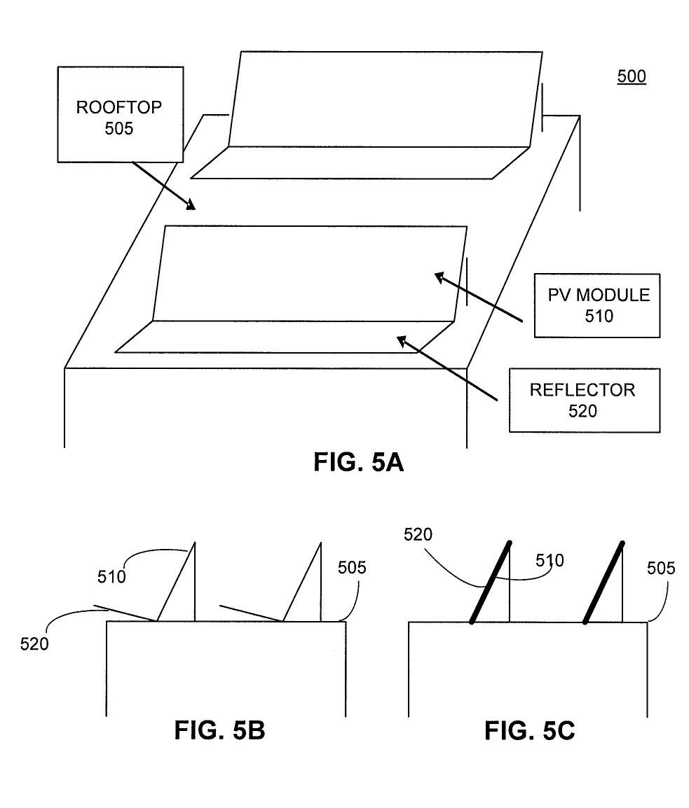

FIGS. 5A, 5B and 5C show various views of a further alternative embodiment of a PV system 500 according to the invention. FIG. 5A shows a front elevation view of the PV system 500 in an open configuration. FIG. 5B shows a side view of the PV system 500 in an open configuration. FIG. 5C shows a side view of the PV system 500 in the closed configuration.

As seen in FIGS. 5A, 5B and 5C, the PV system 500 includes a PV module 510 (e.g., a fixed solar panel) and a movable reflector panel 520 (or cover) mounted to, for example, a flat rooftop 505 of a commercial building. The PV system includes an actuator system (not shown) for moving the movable reflector panel 520 between an open configuration (shown in FIGS. 5A and 5B) and a closed configuration (shown in FIG. 5C). The reflector panel 520 includes back panel. The PV module 510 may be similar to the PV module 110 shown in FIG. 1. The actuator system (not shown) may be similar to the actuator system 220 shown in FIG. 2. The reflector panel 520 may be similar in performance and composition to the reflector panels 120A to 120D shown in FIG. 1A. Further, the back panels of the reflector panel 520 may be similar to the back panels 125A to 125D shown in FIG. 1B. Furthermore, any number of combinations of PV module 510 and movable reflector panel 520 may be mounted to the rooftop 505 of the commercial building.

It is noted that the reflector panels can be configured in a variety of shapes and configurations, so long as the reflector panels are able to fully cover the PV module surface when closed and provide a reflective surface that can increase radiant intensity on the PV cells when open. For example, other shapes and configurations for the reflector panels may include, but are not limited to, circles, squares, ovals, or any other shape capable of being configured into reflector panels that completely cover the PV module sensing surface when safely stowed (i.e., to protect the PV cells in adverse weather conditions and minimize wind resistance) and provide effective reflection to increase radiant energy impinging on the PV cells.

Furthermore, the reflector panels may be configured to slide over the light sensing portion of the PV module, instead of, or in addition to rotating to cover the PV module as shown, e.g., in FIGS. 1A and 1B.

The invention addresses the problem of inefficiencies in solar cells and the elements of the system that convert solar light into usable power. The invention has an additional benefit of being able to protect the PV (or solar) cells under adverse conditions by using the reflective elements of the invention (i.e., the reflector panels) to shield the PV cells. This invention may be used to broaden the applicability of solar systems to locations and environments that typically wouldn't employ PV cells because of cost, climate and/or inefficiencies. The invention may be used to increase the efficiency of solar PV systems, reduce the cost per Kilowatt of output, while also providing a mechanism to protect the PV cells during adverse conditions. Hence, the market for PV systems may be broadened to locations and environments that typically would not (or could not) employ PV cells because of cost, climate and/or inefficiencies.

While the invention has been described in terms of example embodiments, those skilled in the art will recognize that the invention can be practiced with switchable modifications in the spirit and scope of the appended claims. These examples given above are merely illustrative and are not meant to be an exhaustive list of all possible designs, embodiments, applications or modifications of the invention.

What is claimed is:

1. An apparatus that includes an array of solar cells for converting solar energy to electrical power, the apparatus comprising:
a reflector panel configured to reflect solar energy to the array of solar cells; and
an actuator configured to move the reflector panel to a predetermined angular position,
wherein the actuator is further configured to move the reflector panel to a closed position to cover a portion of the array of solar cells.

2. The apparatus according to claim 1, further comprising:
an inverter coupled to the array of solar cells to receive DC power from the array of solar cells,
wherein the inverter is configured to convert the received DC power to AC power.

3. The apparatus according to claim 1, wherein the reflector panel comprises a non-rectangular configuration.

4. The apparatus according to claim 1, wherein the actuator is further configured to move the reflector panel to the closed position based on a sensor feedback signal.

5. The apparatus according to claim 1, wherein the actuator is further configured to move the reflector panel to the closed position based on a manual force exerted by a user.

6. The apparatus according to claim 1, further comprising:
a second reflector panel configured to cover a second portion of the array of solar cells;
a third reflector panel configured to cover a third portion of the array of solar cells; and
a fourth reflector panel configured to cover a fourth portion of the array of solar cells,
wherein the second, third and fourth portions of the array of solar cells are different.

7. The apparatus according to claim 6, wherein said reflector panel and said second, third and fourth reflector panels are each configured to be individually or simultaneously movable to the closed position.

8. The apparatus according to claim 4, wherein the sensor feedback signal comprises at least one of a barometric pressure data, a rain data, an ice data, a snow data, a light data, or a GPS coordinate data.

9. The apparatus according to claim 1, wherein the reflector panel comprises:
a mirror;
a reflective coating;
a reflective film;
a microprism;
a reflective paint; or
a cold light reflector.

10. The apparatus according to claim 9, wherein the reflective film comprises:
a metal;
a metal film; or
a glass bead film.

11. The apparatus according to claim 1, wherein the actuator comprises:
a low-energy consumption device that includes a switch, a relay or a DC motor.

12. The apparatus according to claim 1, wherein the properties of the reflector panel provide for reflectance that includes incident radiation reflected light reflected as a combination of specular and diffuse reflection.

13. A method for optimizing energy retrieval from an array of solar cells and protecting the array of solar cells from weather-related conditions, the method comprising:
moving a reflector panel to a predetermined angular position on the basis of an ambient condition.

14. The method according to claim 13, wherein the predetermined angular position comprises a closed position to cover the array of solar cells.

15. The method according to claim 13, further comprising:
receiving sensor feedback data from a sensor assembly; and
moving the reflector panel to the predetermined angular position based on the sensor feedback data.

16. The method according to claim 15, wherein the sensor feedback data comprises at least one of a barometric pressure data, a rain data, an ice data, a snow data, a light data, or a GPS coordinate data.

17. The method according to claim 13, wherein the moving comprises driving a low-energy consumption DC motor.

18. The method according to claim 14, further comprising:
moving a second reflector panel configured to cover a second portion of the array of solar cells;
moving a third reflector panel configured to cover a third portion of the array of solar cells; and
moving a fourth reflector panel configured to cover a fourth portion of the array of solar cells,
wherein said reflector panel and said second, third and fourth reflector panels are simultaneously moved to completely cover the array of solar cells to protect the cells from weather-related conditions.

19. A computer readable medium comprising a program that, when executed, causes optimizing energy retrieval from an array of solar cells and protecting the array of solar cells from harmful ambient conditions, the medium comprising:
a reflector panel moving code section that, when executed, causes a reflector panel to move to a predetermined angular position on the basis of an ambient condition.

20. The medium according to claim 19, wherein the predetermined angular position comprises a closed position to cover the array of solar cells, the medium further comprising:
a sensor feedback section that, when executed, causes receiving a sensor feedback data from a sensor assembly,
wherein the reflector panel is moved to the predetermined angular position based on the sensor feedback data.

21. The medium according to claim 20, wherein the sensor feedback data comprises at least one of a barometric pressure data, a rain data, an ice data, a snow data, a light data, or a GPS coordinate data.
